(19) United States
(12) Patent Application Publication
(10) Pub. No.: US 2015/0284873 A1
(43) Pub. Date: Oct. 8, 2015

(54) METHODS OF FORMING AND ANALYZING DOPED SILICON

(71) Applicant: HEMLOCK SEMICONDUCTOR CORPORATION, Hemlock, MI (US)

(72) Inventors: Douglas Homer Kreszowski, Saginaw, MI (US); Elizabeth Lanning, Bay City, MI (US)

(21) Appl. No.: 14/441,559

(22) PCT Filed: Dec. 4, 2013
(86) PCT No.: PCT/US2013/073053

§ 371 Date: May 8, 2015

Related U.S. Application Data
(60) Provisional application No. 61/735,777, filed on Dec. 11, 2012.

(51) Int. Cl. C30B 13/10; G01N 21/64; C30B 29/06

(52) U.S. Cl. CPC C30B 13/10; C30B 29/06; G01N 21/6489; G01N 2201/127

(57) ABSTRACT

Methods of forming and analyzing doped monocrystalline silicon each comprise the steps of providing: a vessel, particulate silicon, a dopant, and a float-zone apparatus. The vessel for each method comprises silicon and defines a cavity. The methods each further comprise the steps of combining the particulate silicon and the dopant to form treated particulate silicon, and disposing the treated particulate silicon into the cavity of the vessel. The methods yet further comprise the step of float-zone processing the vessel and the treated particulate silicon into doped monocrystalline silicon with the float-zone apparatus. The analytical method further comprises the step of providing an instrument. The analytical method yet further comprises the steps of removing a piece from the doped monocrystalline silicon, and determining the concentration of the dopant in the piece with the instrument. The methods are useful for forming and analyzing monocrystalline silicon having various types and/or concentrations of dopant(s).

### CROSS REFERENCE TO RELATED APPLICATIONS

This application claims the benefit of U.S. Provisional Patent Application Ser. No. 61/735,777, filed on Dec. 11, 2012, which is incorporated herewith by reference in its entirety.

### BACKGROUND

Disclosed are methods of forming and analyzing silicon, and more specifically methods of forming and analyzing doped monocrystalline silicon.

In the silane manufacturing businesses, there is a need to monitor for electrical impurities which can be imparted to silicon formed from silane. These electrical impurities (or at least certain levels thereof), are undesirable in certain end applications of the silicon. Electrical impurities are often attributed to elements such as boron (B), phosphorus (P), aluminum (Al), arsenic (As), indium (In), gallium (Ga), and/or antimony (Sb). While there are means for quantifying B, P, Al, and As near the parts per trillion atoms (ppta) level using certain technologies, e.g. photoluminescence (PL), conventional technology is not suitable for testing lower levels and/or certain types of elements, such as In, Ga, and Sb near ppta levels and below.

As such, there remains an opportunity to provide improved methods of forming and analyzing silicon for measuring and testing certain impurities and levels thereof in silane used to form silicon. There also remains an opportunity to provide improved doped silicon.

### SUMMARY OF THE INVENTION AND ADVANTAGES

Disclosed is a method of forming doped monocrystalline silicon. The method comprises the steps of providing a vessel, providing particulate silicon, providing a dopant, and providing a float-zone zone apparatus. The vessel comprises silicon and defines a cavity. The method further comprises the step of combining the particulate silicon and the dopant to form treated particulate silicon. The method further comprises the step of disposing the treated particulate silicon into the cavity of the vessel. The method yet further comprises the step of float-zone processing the vessel and the treated particulate silicon into the doped monocrystalline silicon with the float-zone apparatus. This method is useful for forming monocrystalline silicon having various types and/or concentrations of dopant(s), such as for forming monocrystalline silicon having very low levels of doping (e.g. In or Ga doping/dopant in the ppta range). The doped monocrystalline silicon can be used for various end applications. For example, the doped monocrystalline silicon can be used to establish calibration standards, which are useful for calibrating instruments that measure for the dopant in other silicon samples (where the dopant is classified as an impurity) near or below ppta levels. Specifically, the calibrated instruments can be used to quantify certain electrical impurities (e.g. In and Ga) near ppta levels and below, which is useful for reporting such levels as they relate to manufacture of silane used to form the silicon.

Also disclosed is a method of analyzing the concentration of a dopant in doped monocrystalline silicon. The method comprises the steps of providing a vessel, providing particulate silicon, providing a dopant, providing a float-zone apparatus, and providing an instrument for measuring levels of the dopant. The vessel comprises silicon and defines a cavity. The method further comprises the step of combining the particulate silicon and the dopant to form treated particulate silicon. The method further comprises the step of disposing the treated particulate silicon into the cavity of the vessel. The method further comprises the step of float-zone processing the vessel and the treated particulate silicon into the doped monocrystalline silicon with the float-zone apparatus. The method yet further comprises the steps of removing a piece from the doped monocrystalline silicon, and determining the concentration of the dopant in the piece of doped monocrystalline silicon with the instrument. This method is useful for analyzing monocrystalline silicon having various types and/or concentrations of dopant(s), such as for analyzing (or quantifying) very low levels of doping of monocrystalline silicon (e.g. In or Ga doping/dopant in the ppta range). Doping and analysis can be used for quantification of low levels of certain electrical impurities, as well as for other purposes.

### BRIEF DESCRIPTION OF THE DRAWINGS

Other advantages of the present invention will be readily appreciated, as the same becomes better understood by reference to the following detailed description when considered in connection with the accompanying drawings wherein:

FIG. 1 is a graph illustrating the correlation between inductively coupled plasma mass spectrometry (ICP-MS) and photoluminescence (PL) for certain examples of gallium doping;

FIG. 2 is a graph illustrating the correlation between low-temperature Fourier transform infrared spectroscopy (FTIR) and PL for certain examples of gallium doping;

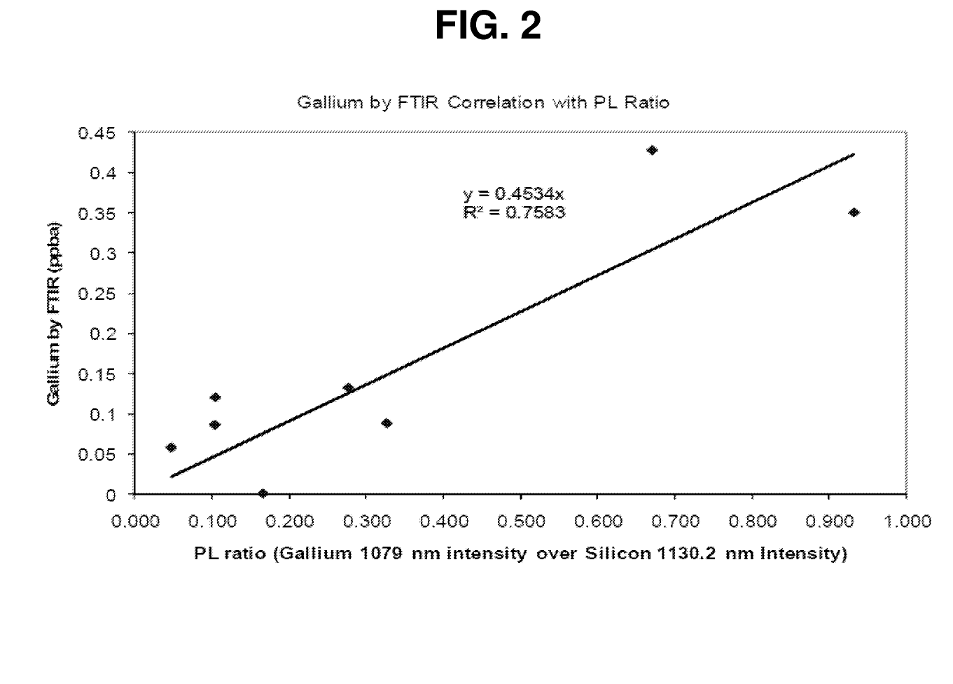

FIG. 3 is a graph illustrating the correlation between surface four-point resistivity and PL for certain examples of gallium doping;

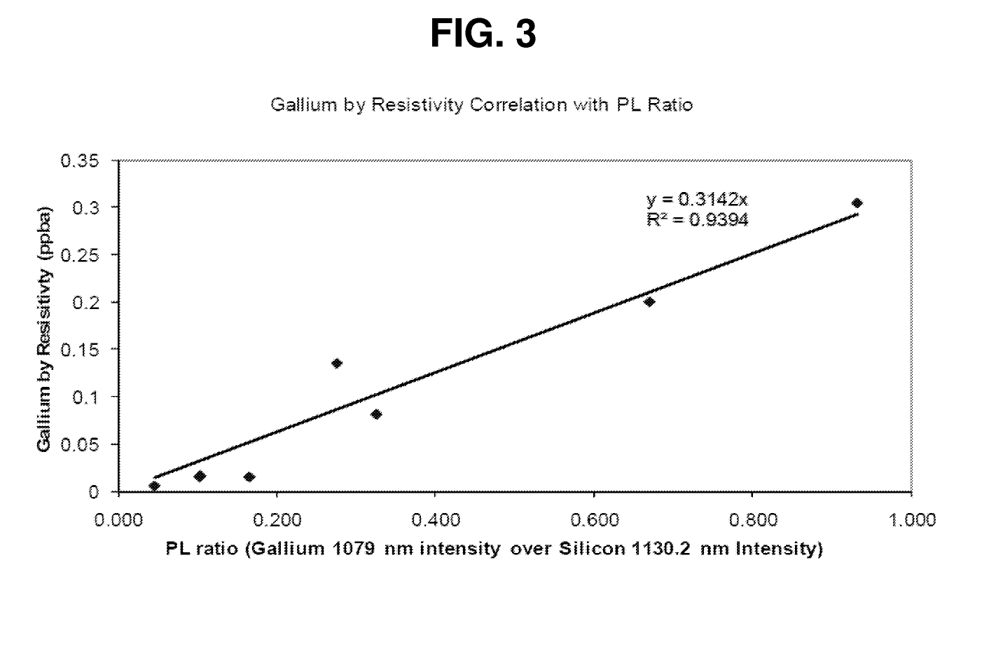

FIG. 4 is a graph illustrating the correlation between ICP-MS and PL for certain examples of indium doping;

FIG. 5 is a graph illustrating the correlation between surface four-point resistivity and PL for certain examples of indium doping;

FIG. 6 is a graph illustrating the calibration curve based on surface four-point resistivity for certain examples of indium doping; and

FIG. 7 is a graph illustrating the calibration curve surface four-point for certain examples of gallium doping.

### DETAILED DESCRIPTION OF THE INVENTION

Disclosed is a method of forming doped monocrystalline silicon (or “method of formation” or “formation method”). Also disclosed is a method of analyzing the concentration of a dopant in doped monocrystalline silicon (or “method of analysis” or “analytical method”). The doped monocrystalline silicon may be one and the same between the two methods, or may be different between the two methods. For example, the lattermost invention method may be used to analyze monocrystalline silicon formed via the former invention method or formed via a different (e.g. conventional) method. The method of forming is described immediately below, whereas the method of analyzing is described further below.

The method of forming generally comprises the steps of providing a vessel, providing particulate silicon, providing a dopant, and providing a float-zone apparatus. The vessel defines a cavity. The method further comprises the step of combining the particulate silicon and the dopant to form treated particulate silicon. The method further comprises the step of disposing the treated particulate silicon into the cavity of the vessel. The method yet further comprises the step of float-zone processing the vessel and the treated particulate silicon into the doped monocrystalline silicon with the float-zone apparatus.

The method is useful for forming doped monocrystalline silicon having various types and/or concentrations of dopant(s). In various embodiments, the method can be used to dope in the parts per trillion atoms (ppta). Other levels of doping, higher or lower than ppta, may also be achieved via the method. Possible end uses for the doped monocrystalline silicon include applications in the medical and electronic fields/industries (e.g. semi-conductor applications). The doped monocrystalline (or single crystal/crystalline) silicon is not limited to any particular use.

The particulate silicon and the dopant can be combined in various manners to form the treated particulate silicon. After combination, the dopant is generally disposed on and/or in the surface of the particulate silicon such that the particulate silicon is “treated”, e.g. surface treated. In certain embodiments, a portion to all of the dopant diffuses into the surface of the particulate silicon. In these embodiments, a concentration of the dopant (i.e., a dopant concentration gradient) generally decreases as surface depth increases. In other embodiments, the dopant is generally fixed on the surface of the particulate silicon with little to no diffusion into the surface itself.

In various embodiments, the dopant is in a liquid such that the dopant can readily contact, cover, and/or coat the surface of the particulate silicon. For example, a solution can be utilized for providing the dopant. In these embodiments, the solution comprises the dopant and a solvent for the dopant. The solution may include one or more different types of dopant and/or solvent. In other embodiments, the dopant itself is in a liquid form, i.e., no solvent is necessarily required. In yet other embodiments, the dopant is in the form of a solid or a gas.

Various types of dopants can be utilized. The dopant is typically selected from the group of transition metals, post-transition metals, metalloids, other nonmetals, and combinations thereof. In certain embodiments, the dopant comprises indium (In), gallium (Ga), or a combination thereof. In specific embodiments, the dopant is In. In other specific embodiments, the dopant is Ga. In other embodiments, the dopant comprises antimony (Sb), aluminum (Al), arsenic (As), bismuth (Bi), thallium (TI), or combinations thereof. In yet other embodiments, the dopant comprises boron (B), phosphorous (P), or a combination thereof. In yet other embodiments, the dopant comprises carbon (C). Various combinations of dopants may be utilized.

In embodiments utilizing the solution, the dopant may be present in the solution in various amounts. Typically, the dopant is present in the solution in an amount of from about 0.0001 to about 100, about 0.0001 to about 75, about 0.001 to about 50, or about 0.01 to about 30, micrograms dopant per gram water (μg/g). In embodiments utilizing In as the dopant, the In is present in the solution in an amount of from about 0.05 to about 100, about 0.05 to about 75, about 0.1 to about 50, or about 0.2 to about 30, μg/g. In embodiments utilizing Ga as the dopant, the Ga is present in the solution in an amount of from about 0.005 to about 10, about 0.005 to about 7.5, about 0.01 to about 5, or about 0.01 to about 2, μg/g. In embodiments utilizing P as the dopant, the P is present in the solution in an amount of from about 0.00005 to about 1, about 0.0001 to about 0.5, about 0.0001 to about 0.1, or about 0.0002 to about 0.05, μg/g. In embodiments utilizing B as the dopant, the B is present in the solution in an amount of from about 0.00005 to about 1, about 0.0001 to about 0.5, about 0.0001 to about 0.1, or about 0.0001 to about 0.02, μg/g. In embodiments utilizing Al as the dopant, the Al is present in the solution in an amount of from about 0.005 to about 20, about 0.005 to about 10, about 0.01 to about 7.5, or about 0.01 to about 6, μg/g. In embodiments utilizing arsenic as the dopant, the arsenic is present in the solution in an amount of from about 0.00005 to about 1, about 0.0001 to about 0.5, about 0.0001 to about 0.1, or about 0.0002 to about 0.05, μg/g. In embodiments utilizing Sb as the dopant, the Sb is present in the solution in an amount of from about 0.0005 to about 5, about 0.001 to about 1, about 0.001 to about 0.5, or about 0.001 to about 0.05, μg/g. In embodiments utilizing Bi as the dopant, the Bi is present in the solution in an amount of from about 0.05 to about 50, about 0.05 to about 30, about 0.01 to about 25, or about 0.1 to about 20, μg/g. In embodiments utilizing Ge as the dopant, the Ge is present in the solution in an amount of from about 0.0005 to about 5, about 0.001 to about 1, about 0.001 to about 0.5, or about 0.001 to about 0.05, μg/g. Higher or lower amounts of dopants may also be utilized, as well as various subranges of the dopants.

Serial dilutions may be used to obtain a desired amount (or concentration) of the dopant in the solution. For example, 1 part per million (ppm) of the dopant can used in a first solution, and one or more solvent dilutions can be used to obtain a final solution having 1 part per trillion (ppt) dopant. Serial dilutions may not be necessary for certain concentrations of the dopant.

If present, various types of solvents can be utilized. Typically, the solvent has a low boiling point (bp), but generally a by higher than room temperature, e.g. a by at or around that of the by of water. In certain embodiments, the solvent is water, such that the solution is an aqueous solution.

The solvent is generally of high purity to prevent undue contamination of the particulate silicon. The solvent need not dissolve/solubilize the dopant, as the solvent need merely act as a carrier/vehicle for applying the dopant to the particulate silicon.

The solution can be applied to the particulate silicon in various manners. In certain embodiments, the solution and the particulate silicon are mixed to obtain wet particulate silicon. The particulate silicon may be partially or fully submerged by the solution. The solution may be applied to the particulate silicon by various manners, such as spraying, dipping, sheeting, tumbling, etc. The method is not limited to any particular application technique.

Typically, the solution and particulate silicon are contacted for a period of time. Various periods of time can be utilized, but should generally be sufficient to transfer a portion to all of the dopant from the solution to the particulate silicon. In general, it is thought that the longer the solution is in contact with the particulate silicon, the greater the amount of dopant that is transferred to the particulate silicon. Generally, it is thought that such a rate (or amount) of transfer of dopant from the solution to the particulate silicon diminishes as time passes, eventually reaching an equilibrium point.

After formation, the wet particulate silicon is typically dried to obtain the treated particulate silicon. The wet particulate silicon may be allowed to dry naturally, or more typically heat is applied to expedite the drying process. The wet particulate silicon may be dried by various means, such as with an oven or belt dryer. The method is not limited to any particular dying technique. In certain embodiments, most to all of the dopant is transferred from the solution to the particulate silicon due to evaporation of the solvent from the solution, leaving the dopant behind.

The source of the particulate silicon which is to be treated via the dopant is not critical. However, one advantage of the method is that the doped monocrystalline silicon is minimally contaminated by the method (if contaminated at all). Therefore, it may be useful when the particulate silicon is of an electronic grade or equivalent. Other grades of particulate silicon may also be used, such as metallurgical grade particulate silicon. Quite simply, the method is not limited to any particular grade of particulate silicon, but the initial purity of the particulate silicon can potentially impact the final purity of the doped monocrystalline silicon. Typically, the particulate silicon comprises polycrystalline (or multi crystal/crystalline) silicon.

Impurities, including electrical impurities, are generally imparted by various elements understood in the art. Examples of such elements include B, P, Al, As, In, Ga, and Sb. Accordingly, in certain instances, an element that is classified as a dopant in one particular embodiment may be classified as an impurity in another. Said another way, in certain embodiments, one or more elements may be considered to be impurities or contaminants; however, in other embodiments, one or more elements may be the dopant (intentionally/purposefully added for purposes of the instant disclosure) as described herein. Such “impurities”, as opposed to “dopants”, may be introduced within silane processes and/or streams which are used to form the particulate silicon.

In certain embodiments, the particulate silicon is free of the dopant prior to combining the particulate silicon and the dopant. However, in other embodiments, the particulate silicon may already have some amount of the dopant (or an alternate dopant different from the dopant) prior to combining with the dopant. The method may be utilized for supplemental doping with either the same or different dopant that may be already be present in the particulate silicon.

The particulate silicon can be provided by various processes understood in the art. In certain embodiments, the particulate silicon is produced in a fluidized-bed process for chemical vapor deposition (CVD) of silane or chlorosilane. For example, the particulate silicon can be polycrystalline silicon particles resulting from the fragmentation of silicon forms produced in a conventional CVD process. The particulate silicon can be monocrystalline particles or fragments. The method is not limited to any particular source or method of manufacture of the particulate silicon.

The particulate silicon can be of various sizes and shapes. In certain embodiments, the particulate silicon is in the form of particles, pellets, chips, flakes, powders, or the equivalent. The size of the particulate silicon should be such that the particles will physically fit into the vessel. Furthermore, the size (or size range) of the particulate silicon should be such that sufficient contact is established between the particles to allow adequate heat transfer to effect float-zone processing. For example, it is possible to float-zone process as large of pieces of silicon as will fit into the vessel if the interstitial space between these pieces is filled with smaller particles of silicon. Generally, the lower limit of particle size is controlled only by the ability to handle the particulate silicon. In certain embodiments, the particulate silicon is particles having a maximum dimension less than about 1 centimeter (cm). Other sizes of the particulate silicon may also be used.

The vessel typically comprises silicon, such that the vessel may also be referred to as a “silicon vessel”. Typically, the vessel consists essentially of silicon, or consists of silicon. The silicon vessel may have trace amounts of its own impurities. The vessel and therefore, the cavity of the vessel, can be of various sizes and shapes, e.g. in the shape of a tube or cylinder. The vessel is used to contain the treated particulate silicon and allow float-zone processing of the treated particulate silicon. The use of a silicon vessel in the float-zone process generally reduces contamination of the treated particulate silicon. Therefore, this process may be used to convert the treated particulate silicon into the doped monocrystalline silicon with low levels of contaminates or impurities (if any at all). The term “silicon vessel” is generally meant to include any means, constructed essentially from silicon, which can contain the treated silicon particles in a manner suitable for float-zone processing. In certain embodiments, the silicon vessel is constructed from polycrystalline or monocrystalline silicon, more typically from polycrystalline silicon.

The size of the vessel is generally dictated by the requirements of the apparatus used to perform the float-zone process. Any diameter for the vessel, which is compatible with the particular float-zone apparatus utilized, is acceptable. In general, the thinner the wall(s) of the vessel the more desirable, since a reduction in vessel bulk minimizes the dilution of the treated particulate silicon during the float-zone process. In addition, it is useful if the vessel has a height sufficient to minimize the segregation of impurities potentially caused by the float-zone. As such, in certain embodiments, the vessel has a height of at least about 5, from about 7 to about 12, or from about 10 to about 12, cm. In general, the upper limit of the vessel height is dictated by the limits imposed by the float-zone process and equipment.

The particular method of forming the vessel is not critical. Any method which creates a vessel composed essentially of silicon and suitable for a float-zone process is acceptable. The method of forming the vessel may be chosen to minimize contamination of the silicon vessel. In certain embodiments, the vessel is constructed by boring and removing a core from a silicon rod (e.g. a polycrystalline rod) formed in a CVD process. The boring can be accomplished by various means, such as with a diamond tipped, stainless steel bore.

The cavity (or bore) typically terminates within the silicon rod such that the vessel has a bottom opposite the opening of the cavity. If the silicon rod is bored all the way through, a plug may be used to close one end of the vessel. If utilized in place of an integral bottom, the plug is typically silicon. The plug can merely be a piece of the bore which is removed from the silicon rod, or may be formed via another method. A cap can be provided to close the open end of the vessel. If utilized, the cap is typically silicon. The cap should be complimentary sized and shaped for closing the cavity of the vessel. The cap can merely be a piece of the silicon rod used to form the vessel, or may be formed via another method. The cap is useful for keeping the treated particulate silicon in place during float-zoning. In certain embodiments, the treated particulate silicon is oriented and packed into the cavity of the vessel in such a manner as to prevent potential “blow out” during float-zoning.

In certain embodiments, the vessel is free of the dopant prior to disposing the treated particulate silicon therein. However, in other embodiments, the vessel may already have some amount of the dopant (or an alternate dopant different from the dopant) prior to float-zoning. Said another way, the method may be utilized for supplemental doping with either the same or different dopant as already present in the vessel and/or particulate silicon.

Prior to float-zoning, the vessel can be cleaned by customary methods, e.g., by solvent wash, acid etching, and water rinsing, either alone, or in any combination. One method for cleaning the vessel is to etch with a mixture of hydrofluoric acid (HF) and nitric acid (HNO₃), followed by an etch mixture of HF, HNO₃, and acetic acid; with a distilled water rinse between each wash, and exhaustive rinsing after the last etch procedure. The same methodology may also be used to clean the particulate silicon.

After disposing the treated particulate silicon, the vessel containing the treated particulate silicon is float-zone processed. The float-zone process can be any one of many processes described in the art and is not limited to those described herein. The float-zone process can be, e.g., a process where the vessel containing the treated particulate silicon is gripped at its open (or capped) end and held vertically in a vacuum chamber or in a chamber filled with a protective gas. A small portion of the length of the vessel containing treated particulate silicon is heated by a heating source, e.g., an induction heating coil or a radiation heating source, so that a molten zone is formed at this point and, by relative movement between the heating source and the vessel, the molten zone is passed through the vessel and treated particulate silicon, from one end to the other.

If a seed crystal is contacted with the initial molten end of the vessel, a silicon rod of doped monocrystalline silicon can be formed. The seed crystal may be a rod portion grown in monocrystalline form by previous treatment. The cross-sectional area of the doped monocrystalline silicon rod can be controlled or regulated by various measures. For example, the molten zone can be compressed or stretched by moving the end holding the crystal in relation to the end holding the silicon vessel toward or away from each other. Additional passes of the heating source along the created doped monocrystalline silicon rod can be performed to potentially effect purification of the silicon.

After formation, the dopant can be present in the doped monocrystalline silicon in various amounts. Typically, the dopant is present in an amount of from about 0.0001 to about 2000, about 0.0005 to about 1000, about 0.001 to about 1000, about 0.01 to about 750, about 0.05 to about 600, or about 0.5 to about 500, ppta (where ppt is 1*10⁻¹²). In other embodiments, the dopant may be present in the doped monocrystalline silicon at higher levels, such as in the parts per billion atoms (ppba) or part per million atoms (ppma) range. Such ranges may be achieved, e.g., via utilization of higher levels of the dopant in the solution used to treat the particulate silicon.

The method of analyzing generally comprises the steps of providing a vessel, providing particulate silicon, providing a dopant, providing a float-zone apparatus, and providing an instrument for measuring levels of the dopant. Each of the vessel, the particulate silicon, and the dopant, can individually be the same as or different from those described in the method of formation. The instrument is described further below.

The method further comprises the step of combining the particulate silicon and the dopant to form treated particulate silicon. The method further comprises the step of disposing the treated particulate silicon into the cavity of the vessel. The method further comprises the step of float-zone processing the vessel and the treated particulate silicon into the doped monocrystalline silicon with the float-zone apparatus. Each of these steps can individually be the same as or different from those described in the method of formation. The method of analyzing is useful for analyzing monocrystalline silicon having various types and/or concentrations of dopant(s).

The method yet further comprises the steps of removing a piece from the doped monocrystalline silicon. Typically, the piece is a slice (or wafer) which is removed from the doped monocrystalline silicon (e.g. a doped silicon rod or zone vessel core). The slice is taken from the float-zoned region of the doped monocrystalline silicon. The slice can be of various thicknesses, and typically has an average thickness less than about 2, of from 1.5 to about 1, or about 1.1, millimeters (mm).

The method yet further comprises the step of determining the concentration of the dopant in the piece, e.g. the slice, of doped monocrystalline silicon with the instrument. Various types of instruments can be utilized. In various embodiments, the instrument is a photoluminescence (PL) instrument. For example, precise measurement of certain dopants can be made by means of PL analysis of etched wafers cut from a rod of doped monocrystalline silicon. In certain embodiments, measurements such as resistivity are made directly on the rod of doped monocrystalline silicon. Standard procedures for PL analysis may be used, e.g., those procedures described by Tajima, Jap. Ann. Rev. Electron. Comput. and Telecom. Semicond. Tech., p. 1-12, 1982. Carbon can be measured, e.g., by Fourier Transformed infrared spectroscopy analysis of etched wafers cut from the rod of doped monocrystalline silicon.

In certain embodiments, the method further comprises the step of calibrating the instrument prior to determining the concentration of the dopant in the piece of doped monocrystalline silicon. Typically, the instrument is calibrated by providing calibration standards and entering the calibration standards into the instrument, e.g. the PL instrument. This is useful for quantifying the concentration of the dopant in the piece of the doped monocrystalline silicon. In various embodiments, the calibration standards are provided by testing the surface resistivity of a doped monocrystalline silicon wafer having a predetermined level of doping. Such a wafer can be obtained via the method of formation. The instant disclosure can be used for a variety of applications including, but not limited to: analytical, testing, and/or quality control applications; manufacturing applications; research and development applications; etc.

The following examples, illustrating the methods of the instant disclosure, are intended to illustrate and not to limit the invention.

### EXAMPLES

### Doping:

Vessel zoning (or float-zoning) is elected based on issues with surface doping encountered during comparative testing. Gas doping is understood as being unsafe with heavy metals. It is desirable to create In and Ga standards within 0.002 to 0.2 ppba range, which can be used to calibrate instruments. The desired amount of atoms of dopant doped into the doped monocrystalline silicon is calculated based on the 8 equations outlined below.

$$\begin{matrix}Water ( g ) = Quant . \_of \_source ( µL ) ⋆ {10}^{- 6} ⋆ ( \frac{Density\_of \_Water}{{10}^{- 3}} ) & Equation 1 \\ Dopant ( g ) = source\_Quant . ( ppm w ) ⋆ ( \frac{water ( g )}{{10}^{6}} ) & Equation 2 \\ Dopant ( moles ) = \frac{Dopant ( g )}{Atomic\_Weight} & Equation 3 \\ Dopant ( atoms ) = \frac{Dopant ( moles )}{6.022 ⋆ {10}^{23}} & Equation 4 \\ Si ( moles ) = \frac{Si ( g )}{Atomic\_Weight} & Equation 5 \\ Si ( atoms ) = Si ( moles ) ⋆ ( 6.022 ⋆ {10}^{23} ) & Equation 6 \\ Theor . \_Conc . \_of \_Dopant \_after {\_K}_{seg} = ( \frac{Dopant ( atoms )}{Si ( atoms )} ) ⋆ {10}^{9} ⋆ {K}_{seg} & Equation 7 \\ Efficiency = \frac{Assigned\_Dopant \_Value ( ppba )}{Theo . \_Conc . \_of \_Dopant} & Equation 8\end{matrix}$$

Table A below provides inputs for the 8 equations above:

TABLE A
Equation Inputs

| Variable | Value |
|---|---|
| Density of Water | 0.997 g/10⁻³ L |
| Mass of Si | 15 g |
| Moles of Si | 0.534 |
| Atoms of Si | 3.22E+23 |
| K_{seg} (In) | 3.64E−04 |
| K_{seg}(Ga) | 1.86E−02 |

The mass of silicon for float-zoning is approximated at 15 grams, which includes the mass of the vessel contents (i.e., the particulate silicon) plus the mass of the vessel walls. Using the equations and assumptions above, theoretical values for In and Ga concentrations within the doped monocrystalline silicon cores are calculated.

Tables 2a and 2b below includes calculations and basic recipes for each of the primary and back-up standards created. Each standard is run on a PL instrument, and the slice contents are quantified using an alternate testing method. The assigned value for each primary and back-up standard is also included in Tables 2a and 2b, so that the efficiency of the doping process can be assessed (Eff. (%)).

TABLE 2a
Dopant Calculations Equations - Indium (In)

| | | | | | | | Theoretical | | |
|---|---|---|---|---|---|---|---|---|---|
| Dopant: | Source | Source | | | | | Value | Assigned | |
| Indium | Quantity | Volume | Water | Dopant | Dopant | Dopant | after Kseg | Values | Eff. |
| (In) | (ppmw) | (uL) | (g) | (grams) | (moles) | (atoms) | (ppba) | (ppba) | (%) |
| In | 1000 | 6 | 0.006 | 5.9820E−06 | 5.2099E−08 | 3.14E+16 | 0.0355 | 0.0004 | 1.13 |
| In | 1000 | 60 | 0.0598 | 5.9820E−05 | 5.2099E−07 | 3.14E+17 | 0.3551 | 0.0016 | 0.45 |
| In | 1000 | 60 | 0.0598 | 5.9820E−05 | 5.2099E−07 | 3.14E+17 | 0.3551 | 0.0228 | 6.42 |
| In | 1000 | 600 | 0.5982 | 5.9820E−04 | 5.2099E−06 | 3.14E+18 | 3.5509 | 0.0550 | 1.55 |
| In | 1000 | 600 | 0.0598 | 5.9820E−05 | 5.2099E−07 | 3.14E+17 | 0.3551 | 0.0015 | 0.42 |
| In | 1000 | 60 | 0.0598 | 5.9820E−05 | 5.2099E−07 | 3.14E+17 | 0.3551 | 0.0140 | 3.94 |
| In | 100 | 6300 | 6.2811 | 5.9820E−04 | 5.2099E−06 | 3.14E+18 | 3.7284 | 0.0008 | 0.02 |
| In | 1000 | 600 | 0.5982 | 5.9820E−04 | 5.2099E−06 | 3.14E+18 | 3.5509 | 0.5740 | 16.16 |

TABLE 2b
Dopant Calculations Equations - Gallium (Ga)

| | | | | | | | Theoretical | | |
|---|---|---|---|---|---|---|---|---|---|
| Dopant: | Source | Source | | | | | Value | Assigned | |
| Gallium | Quantity | Volume | Water | Dopant | Dopant | Dopant | after Kseg | Values | Eff. |
| (Ga) | (ppmw) | (uL) | (g) | (grams) | (moles) | (atoms) | (ppba) | (ppba) | (%) |
| Ga | 1 | 317 | 0.3160 | 3.1605E−07 | 4.5331E−09 | 2.7298E+15 | 0.1579 | 0.0053 | 3.36 |
| Ga | 1 | 317 | 0.3160 | 3.1605E−07 | 4.5331E−09 | 2.7298E+15 | 0.1579 | 0.0151 | 9.56 |
| Ga | 10 | 317 | 0.3160 | 3.1605E−06 | 4.5331E−08 | 2.7298E+16 | 1.579 | 0.0812 | 5.14 |
| Ga | 10 | 3170 | 3.1605 | 3.1605E−05 | 4.5331E−07 | 2.7298E+17 | 15.79 | 0.1997 | 1.26 |
| Ga | 1 | 317 | 0.3160 | 3.1605E−07 | 4.5331 E−09 | 2.7298E+15 | 0.1579 | 0.0163 | 10.32 |
| Ga | 10 | 3170 | 3.1605 | 3.1605E−05 | 4.5331 E−07 | 2.7298E+17 | 15.79 | 0.3041 | 1.93 |

To determine efficiency, a segregation value must be assigned. The segregation values cited in literature for zoning processes can be quite variable. Furthermore, actual segregation coefficients for the zoning equipment being utilized may be quite different from the values cited in literature, so segregation values are independently determined for the In and Ga species.

Silicon from the float-zoned melt region of the doped monocrystalline silicon is dissolved in concentrated acid using a conventional “Total Digestion Process”, and the solution is analyzed using ICP-MS. Using this approach, segregation values of about 1.86E-02 for Ga and of about 3.64E-04 for In are determined. Based on these segregation assignments, the efficiency of the doping process varies between about 0.5 to about 16% for this sample set, as illustrated in Table 2a and 2b.

### Quantification of Doped Samples:

Each of 3 techniques (4-point resistivity measurement followed by conversion into dopant density, sample dissolution followed by ICP-MS measurement of the impurity, and direct measurement of impurity with low temperature FTIR) can present technical issues. Most of the technical issues are due to the low desired calibration range (0.001 to 0.2 ppba).

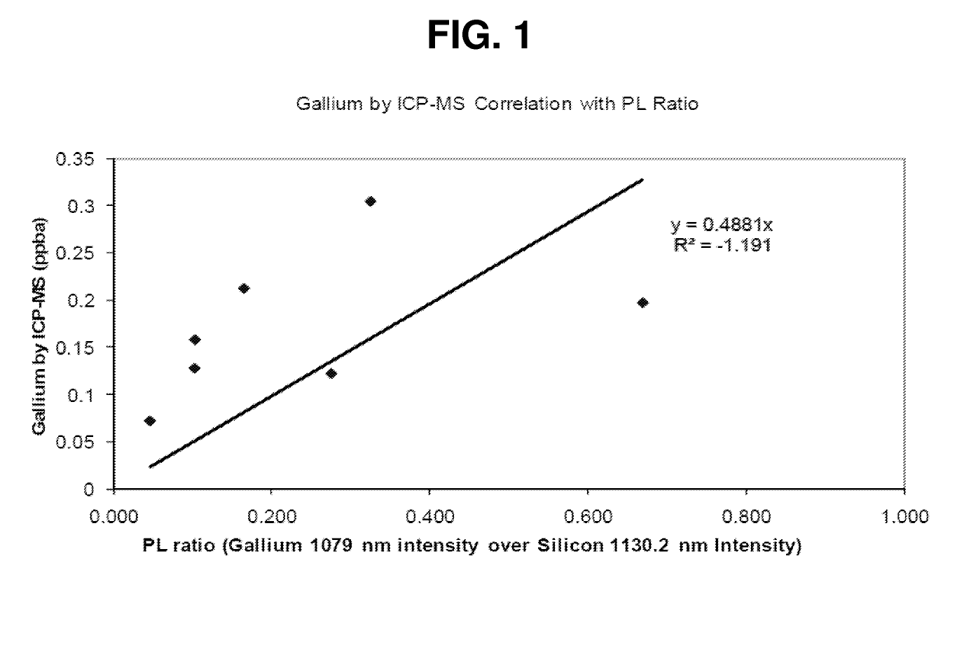

Ga test comparisons offer an ability to directly compare the 3 techniques for quantifying impurity values against the spectral response from the PL instrument. In FIGS. 1 though 3, the ratio of integrated areas between the Ga 1079.0 nm peak and the Si Free Exciton 1130.2 nm peak for 8 different Ga-doped samples are correlated with the results from the ICP-MS, FTIR, or 4-Point Resistivity technique. Ultimately, it is determined that the resistivity test should be used for characterizing the Ga values on the Ga PL calibration standards.

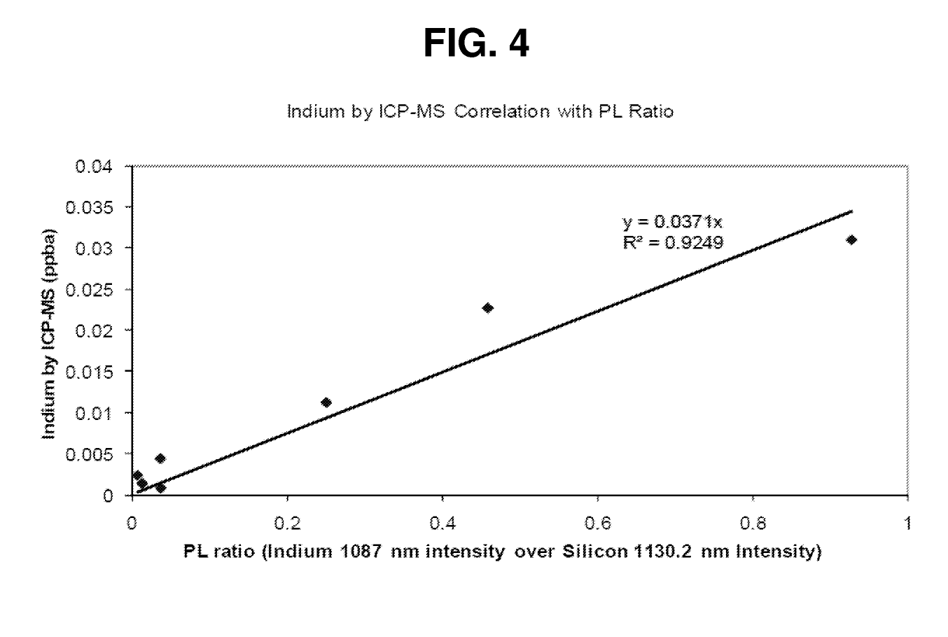

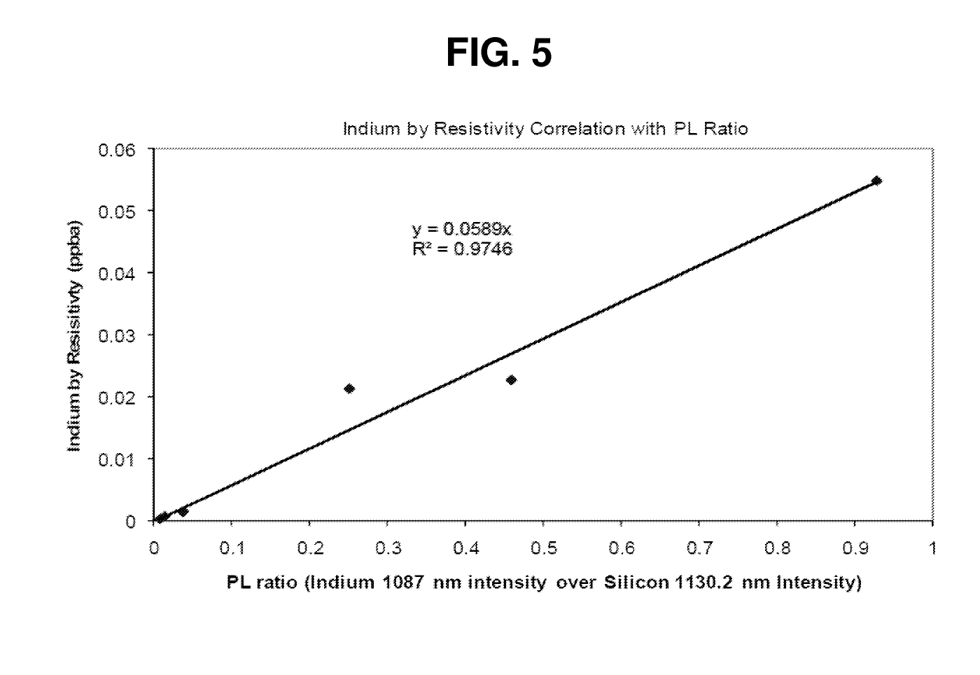

The In comparison is limited to either ICP-MS or 4-Point Resistivity since the detector used on CryoSAM typically interferes with the In measurement on low-temperature FTIR. In this case, both techniques had approximately equal fit, as shown in FIGS. 4 and 5, though there is some discrepancy in the response factors between the 2 techniques. The resistivity results are more linear with the PL ratio at the lower (sub 10 ppta) In concentrations, which may indicate some better sensitivity with the resistivity test. Thus, the resistivity test is also used for characterizing the In values on the In PL calibration standards. It is thought that the ICP-MS test method sensitivity can be improved by using a combination of larger test samples (increase from the 1.6 grams) or smaller dilution rates (10 ml used). This is based on the understanding that the ICP-MS technique generally becomes more sensitive with the heavier elements on the periodic table.

The mechanism for doping In and Ga into polycrystalline silicon to form In or Ga doped single crystalline cores is summarized hereafter. Different concentrations are derived based on the calculation profiles summarized in Tables 2a and 2b. Source solutions of 1000 ppmw In and 10 ppmw Ga are obtained from a manufacturer of traceable NIST Standards.

TABLE 3
Dopant NIST Standard Source Solution Quantities

| | Source Solution | Quantity of Source |
|---|---|---|
| Dopant: Indium (In) | Concentration | Solution |
| or Gallium (Ga) | (ppmw) | (uL) |
| In | 1000 | 6 |
| In | 1000 | 60 |
| In | 1000 | 600 |
| Ga | 1 | 317 |
| Ga | 10 | 317 |
| Ga | 10 | 3170 |
| In | 1000 | 600 |
| In | 1000 | 600 |
| In | 1000 | 600 |
| In | 1000 | 600 |
| Ga | 1 | 317 |
| Ga | 1 | 317 |

Different volumes are extracted from the source solution using a micropipette. A desired amount of In or Ga standard from Table 3 is added to a 60 mL vial. Next, 10 mL of distilled water is added to the vial. Non-washed silicon particulate (Si chips) is then added to the vial. Additional distilled water is added to the vial until the Si chips are submerged. The vial is capped and inverted several times. The vial is placed with cap off on a hot block set at 140° C. The Si chips are allowed to dry over night to obtain treated Si chips.

Using an etched vessel, the treated Si chips are packed into the vessel and float-zoned using a conventional float-zone process. At a cut point >2 centimeters (cm), slices approximately 1.1 mm thick are cut from the float-zoned region and etched. The resistivity from the surface of the slice is used in conjunction with PL results for B, P, Al, and As values to assign impurity values based on resistivity numbers to the In or Ga spectral peaks.

Quantification of the PL spectral peaks for In or Ga is completed by creating calibration curves based on measuring integrated area ratios between the In (1086.8 nm) or Ga (1079.0 nm) peak relative to the area surrounding the silicon free exciton lines (1128.6 nm and 1130.2 nm).

Slices containing In or Ga are made with assigned contamination levels ranging from 0.0004 to 0.5740 ppba and used as 4-point calibration sets. Additional samples are derived for back-up calibration samples as well as for instrument auditing material. Segregation values are derived for In and Ga based on operating run conditions for the float-zone apparatus.

The process for placing the treated Si chips inside the vessel may also be referred to as packing. To pack the vessel (e.g. a hollowed core), a few treated Si chips are added to the vessel. A light (e.g. a flashlight) is used such that one can view the bottom of the hollowed core. Clean ceramic tweezers are used to carefully lift up treated Si chips that are positioned horizontally. The vessel can be gently tapped while packing. If one taps the vessel too aggressively when packing, the Si plug or bottom of the vessel can crack and fall off during pre-heat. The vessel is filled to ˜0.5 to ˜1 cm from its top. The vessel is then capped with a clean silicon tang. The cap is used to reduce the amount of treated Si chip from blowing out of the vessel during zoning.

Development of In and Ga PL calibration standard samples requires initial creation of single crystal silicon test slices using given float-zone testing technology, followed by quantification of the qualitative PL spectra using an alternate test technology that can measure In or Ga values independent of the PL measurement for the desired calibration range (approximately 0.002 to 0.200 ppba). The In and Ga standards are developed independently to permit secondary calibration using 4-point Resistivity test equipment. However, other alternatives were investigated during the course of standard sample development.

### Alternate Testing Technology:

3 alternatives for qualifying PL are explored for measuring In and Ga concentrations within prepared single crystal silicon slices: 1) Total dissolution of the slice and subsequent measurement using ICP-MS; 2) low-temperature FTIR testing of electrical impurities; and 3) 4-point surface resistivity measurement of the standard slice.

### ICP-MS:

The ICP-MS technique is a destructive test that involves dissolution of silicon, yet the sample slice itself must be retained whole for future calibration needs. Thus, samples of known mass are taken from a doped vessel core at positions above and below a chosen test slice, and the silicon is dissolved using a 50:50 mixture of HF:HNO₃. The residuals are then dissolved in 10 mL solutions before evaluation on a Perkin-Elmer ICP-MS. The final assignment of values is based on averaging dopant values from both mass samples, assuming this average reflects the impurity value of the middle sample slice.

### Low-Temperature FTIR

A low-temperature FTIR technique (CryoSAM) is utilized to measure the Ga concentration in a sample slice. The FTIR sample slices are prepared from doped vessel cores and submitted for evaluation via FTIR.

### 4-Point Resistivity

Measurements are conducted using surface 4-point resistivity on sample slices that are approximately 15.5 mm in diameter, and 1.1 mm thick. The sample slices are doped with either In or Ga. Regardless of the dopant, the slices contained varying levels of B and P impurities, which contributes to net resistivity. As such, the impurities need to be accounted for when determining the In or Ga concentrations. Thus, B and P values as measured from PL testing are subtracted from the resistivity to produce a net resistivity for the dopant (In or Ga). Resistivity is measured following procedures listed in SEMI standard MF-84, “Standard Test Method for Measuring Resistivity of Silicon Wafers With an In-Line Four-Point Probe”.

Resistivity calculations for the sample slices are performed offline on a spreadsheet which follows the calculation procedures in SEMI Standard MF-84. A temperature correction is applied.

The samples are also type tested following the strictures of SEMI standard MF-42 for Test Method C: “Point-Contact Rectification Conductivity-Type Test” to identify the dominant species. Once the resistivity and the conductivity type values are identified, the resistivity value is converted to Dopant density using SEMI standard MF-723.

Due to extreme low levels of impurities (e.g. B and/or P), and often high resistivity values, many of the correction factors need to be extrapolated beyond the normal ranges cited in the SEMI standards. Within SEMI MF-84, the F2, F(w/S), and FT factors require such adjustment. The tables in SEMI MF-723 require a similar extrapolation. Next, the B and P values, as measured by a calibrated PL instrument, are subtracted from the dopant density value calculated using SEMI MF-723 to assign the remaining dopant density to the given dopant (In or Ga). The head of the test probe is changed from 1.6 mm spacing to 1.0 mm spacing. This narrower spacing improves accuracy and quality of test results.

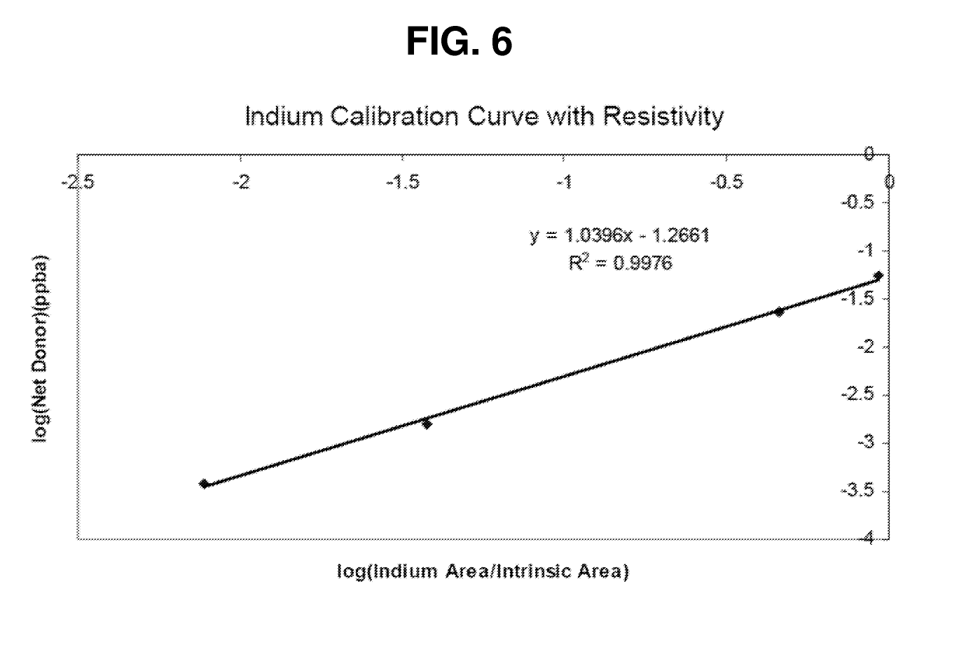

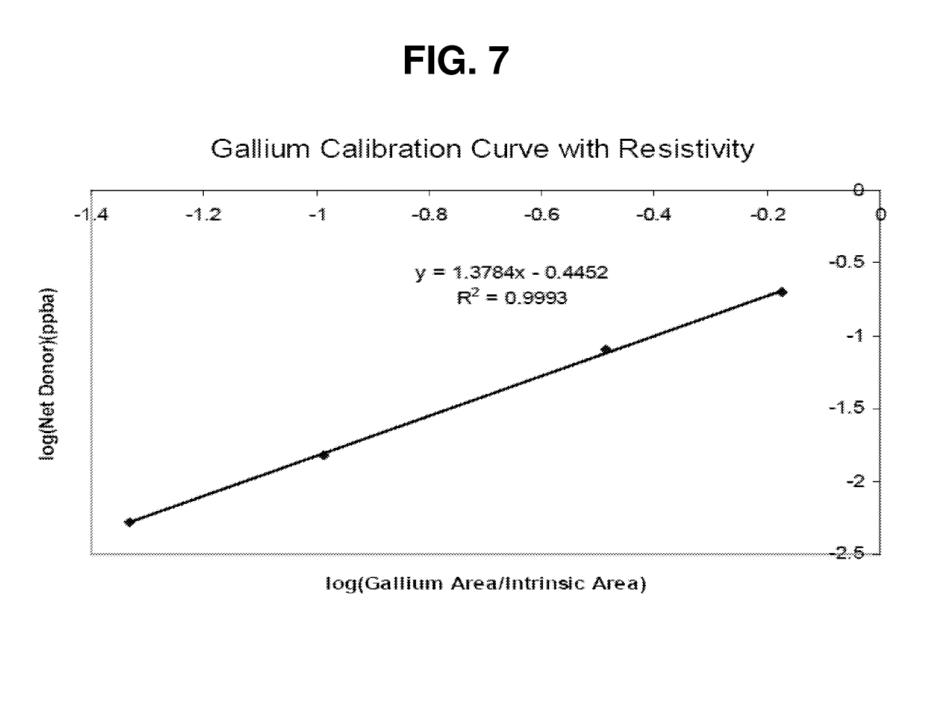

Results using appropriate coefficients from SEMI standard MF-84 and MF-723 are listed in Tables 4 (In Resistivity and PL Data) and Tables 5 (Ga Resistivity and PL Data) below. Example calibration curves from one of the calibrated PL instruments are provided for In (in FIG. 6) and Ga (in FIG. 7).

TABLE 4
Indium Resistivity and PL Data

| | | | | Probe-tip | Slice | Thick- | Probe Head |
|---|---|---|---|---|---|---|---|
| | | Recipe | Sample | Spacing | Diameter | ness | Correction |
| Dopant | Type | Type¹ | No. | (mm) | (mm) | (mm) | Factor |
| Indium | Primary | 10000 | 352607 | 1 | 17.08 | 2.114 | 0.992 |
| | | | | 1 | 17.08 | 2.114 | 0.992 |
| | | | | 1 | 17.08 | 2.114 | 0.992 |
| | | | | 1 | 17.08 | 2.114 | 0.992 |
| Indium | Primary | 1.00E+05 | 352608 | 1 | 15.52 | 2.095 | 0.992 |
| | | | | 1 | 15.52 | 2.095 | 0.992 |
| | | | | 1 | 15.52 | 2.095 | 0.992 |
| | | | | 1 | 15.52 | 2.095 | 0.992 |
| Indium | Primary | 1.00E+05 | 351974 | 1 | 15.35 | 2.112 | 0.992 |
| | | | | 1 | 15.35 | 2.112 | 0.992 |
| | | | | 1 | 15.35 | 2.112 | 0.992 |
| | | | | 1 | 15.35 | 2.112 | 0.992 |
| Indium | Primary | 1M | 352669 | 1 | 15.06 | 2.088 | 0.992 |
| | | | | 1 | 15.06 | 2.088 | 0.992 |
| | | | | 1 | 15.06 | 2.088 | 0.992 |
| | | | | 1 | 15.06 | 2.088 | 0.992 |
| Indium | Back-Up | 1M | 352670 | 1 | 15.68 | 2.085 | 0.992 |
| | | | | 1 | 15.68 | 2.085 | 0.992 |
| | | | | 1 | 15.68 | 2.085 | 0.992 |
| | | | | 1 | 15.68 | 2.085 | 0.992 |
| Indium | Back-Up | 1000 | 351969 | 1 | 16.49 | 2.119 | 0.992 |
| | | | | 1 | 16.49 | 2.119 | 0.992 |
| | | | | 1 | 16.49 | 2.119 | 0.992 |
| | | | | 1 | 16.49 | 2.119 | 0.992 |
| Indium | Back-Up | 1.00E+05 | 352494 | 1 | 17.02 | 2.113 | 0.992 |
| | | | | 1 | 17.02 | 2.112 | 0.992 |
| | | | | 1 | 17.02 | 2.112 | 0.992 |
| | | | | 1 | 17.02 | 2.112 | 0.992 |
| Indium | Back-Up | 1.00E+05 | 352834 | 1 | 15.61 | 2.115 | 0.992 |
| | | | | 1 | 15.61 | 2.115 | 0.992 |
| | | | | 1 | 15.61 | 2.115 | 0.992 |
| | | | | 1 | 15.61 | 2.115 | 0.992 |

| | | | | | | | | | Sheet |
|---|---|---|---|---|---|---|---|---|---|
| Dopant | S/D | F2 | w/S | F(w/s) | F | Voltage | Current (I) | Resistance | Resistance |
| Indium | 0.059 | 4.423 | 2.114 | 0.305 | 2.834 | 1.22E−04 | 5.00E−09 | 24485.466 | 69382.466 |
| | 0.059 | 4.423 | 2.114 | 0.305 | 2.834 | 1.36E−04 | 5.00E−09 | 27299.068 | 77355.141 |
| | 0.059 | 4.423 | 2.114 | 0.305 | 2.834 | 1.17E−04 | 5.00E−09 | 23335.842 | 66124.871 |
| | 0.059 | 4.423 | 2.114 | 0.305 | 2.834 | 1.26E−04 | 5.00E−09 | 25251.896 | 71554.236 |
| Indium | 0.064 | 4.388 | 2.095 | 0.321 | 2.928 | 3.37E−04 | 1.00E−08 | 33687.685 | 98637.024 |
| | 0.064 | 4.388 | 2.095 | 0.321 | 2.928 | 3.44E−04 | 1.00E−08 | 34373.415 | 100644.831 |
| | 0.064 | 4.388 | 2.095 | 0.321 | 2.928 | 3.41E−04 | 1.00E−08 | 34080.95 | 99788.498 |
| | 0.064 | 4.388 | 2.095 | 0.321 | 2.928 | 3.39E−04 | 1.00E−08 | 33894.385 | 99242.239 |
| Indium | 0.065 | 4.383 | 2.112 | 0.307 | 2.821 | 6.13E−04 | 2.50E−08 | 24521.694 | 69167.003 |
| | 0.065 | 4.383 | 2.112 | 0.307 | 2.821 | 6.22E−04 | 2.50E−08 | 24864.56 | 70134.106 |
| | 0.065 | 4.383 | 2.112 | 0.307 | 2.821 | 6.15E−04 | 2.50E−08 | 24594.296 | 69371.788 |
| | 0.065 | 4.383 | 2.112 | 0.307 | 2.821 | 6.29E−04 | 2.50E−08 | 25173.152 | 71004.535 |
| Indium | 0.066 | 4.376 | 2.088 | 0.327 | 2.962 | 2.44E−04 | 3.00E−08 | 8146.687 | 24130.771 |
| | 0.066 | 4.376 | 2.088 | 0.327 | 2.962 | 2.44E−04 | 3.00E−08 | 8131.563 | 24085.975 |
| | 0.066 | 4.376 | 2.088 | 0.327 | 2.962 | 2.42E−04 | 3.00E−08 | 8072.743 | 23911.748 |
| | 0.066 | 4.376 | 2.088 | 0.327 | 2.962 | 2.44E−04 | 3.00E−08 | 8148.378 | 24135.782 |
| Indium | 0.064 | 4.392 | 2.085 | 0.329 | 2.991 | 1.13E−04 | 1.50E−07 | 750.633 | 2244.862 |
| | 0.064 | 4.392 | 2.085 | 0.329 | 2.991 | 1.13E−04 | 1.50E−07 | 752.649 | 2250.893 |
| | 0.064 | 4.392 | 2.085 | 0.329 | 2.991 | 1.12E−04 | 1.50E−07 | 743.572 | 2223.747 |
| | 0.064 | 4.392 | 2.085 | 0.329 | 2.991 | 1.12E−04 | 1.50E−07 | 746.934 | 2233.801 |
| Indium | 0.061 | 4.41 | 2.119 | 0.301 | 2.794 | 1.04E−04 | 4.00E−09 | 26005.729 | 72656.033 |
| | 0.061 | 4.41 | 2.119 | 0.301 | 2.794 | 1.06E−04 | 4.00E−09 | 26409.099 | 73782.987 |
| | 0.061 | 4.41 | 2.119 | 0.301 | 2.794 | 1.10E−04 | 4.00E−09 | 27417.509 | 76600.33 |
| | 0.061 | 4.41 | 2.119 | 0.301 | 2.794 | 1.10E−04 | 4.00E−09 | 27417.575 | 76600.515 |
| Indium | 0.059 | 4.422 | 2.113 | 0.306 | 2.839 | 1.87E−04 | 1.25E−08 | 14957.52 | 42466.467 |
| | 0.059 | 4.422 | 2.112 | 0.306 | 2.838 | 1.86E−04 | 1.25E−08 | 14876.836 | 42217.404 |
| | 0.059 | 4.422 | 2.112 | 0.306 | 2.838 | 1.82E−04 | 1.25E−08 | 14578.34 | 41370.334 |
| | 0.059 | 4.422 | 2.112 | 0.306 | 2.838 | 1.84E−04 | 1.25E−08 | 14703.372 | 41725.149 |
| Indium | 0.064 | 4.39 | 2.115 | 0.305 | 2.806 | 1.26E−04 | 5.00E−09 | 25211.539 | 70744.613 |
| | 0.064 | 4.39 | 2.115 | 0.305 | 2.806 | 1.19E−04 | 5.00E−09 | 23708.958 | 66528.309 |
| | 0.064 | 4.39 | 2.115 | 0.305 | 2.806 | 1.23E−04 | 5.00E−09 | 24626.613 | 69103.287 |
| | 0.064 | 4.39 | 2.115 | 0.305 | 2.806 | 1.15E−04 | 5.00E−09 | 23053.432 | 64688.876 |

| | Average | | Temp. | Temp. | | | Phosphorus |
|---|---|---|---|---|---|---|---|
| | Sheet | Average | Correction | Correction | Temp. | Final | by PL |
| Dopant | Resistance | Resistivity | (C_{T}) | Factor (FT) | (° C.) | Resistivity | (ppba) |
| Indium | 71104.179 | 15031.423 | 0.009 | 0.964 | 26.778 | 14496.302 | 0.0359 |
| Indium | 99578.148 | 20861.622 | 0.009 | 0.964 | 26.772 | 20114.878 | 0.0329 |
| Indium | 69919.358 | 14766.968 | 0.009 | 0.964 | 26.778 | 14241.46 | 0.0279 |
| Indium | 24066.069 | 5024.995 | 0.009 | 0.965 | 26.828 | 4847.952 | 0.0275 |
| Indium | 2238.326 | 466.691 | 0.009 | 0.967 | 26.789 | 451.256 | 0.0314 |
| Indium | 74909.966 | 15873.422 | 0.009 | 0.964 | 26.8 | 15304.343 | 0.0193 |
| Indium | 41944.838 | 8858.75 | 0.009 | 0.965 | 26.8 | 8545.081 | 0.0201 |
| Indium | 67766.271 | 14332.566 | 0.009 | 0.964 | 26.772 | 13823.589 | 0.0284 |

| | Boron | Aluminum | Donor | Donor | Net Donor | Instrinsic | Indium |
|---|---|---|---|---|---|---|---|
| | by PL | by PL | by PL | by Resist | Amt. = Indium | Silicon | Peak |
| Dopant | (ppba) | (ppba) | (ppba) | (ppba) | (ppba) | Peak Area² | Area³ |
| Indium | 0.0498 | 0.004 | 0.0179 | 0.0183 | 0.0004 | 22.896 | 0.177 |
| Indium | 0.0403 | 0.0042 | 0.0116 | 0.0132 | 0.0016 | 15.97 | 0.604 |
| Indium | 0.0189 | 0.0048 | −0.0042 | 0.0186 | 0.0228 | 5.298 | 2.431 |
| Indium | 0.0272 | 0 | −0.0003 | 0.0547 | 0.055 | 8.079 | 7.499 |
| Indium | 0.0447 | 0 | 0.0133 | 0.5873 | 0.574 | 0.982 | 5.607 |
| Indium | 0.0279 | 0.0079 | 0.0165 | 0.0173 | 0.0008 | 11.955 | 0.164 |
| Indium | 0.0297 | 0.0074 | 0.017 | 0.031 | 0.014 | 3.19 | 0.8 |
| Indium | 0.0208 | 0 | −0.0076 | −0.0061 | 0.0015 | 40.387 | 1.507 |

| | log(Indium | log(Net | Assigned Calibra- | Indium Calculation | Fit between |
|---|---|---|---|---|---|
| | Area/Intrin- | Donor Amt.) | tion Value per | per Calibration | Curve and |
| Dopant | sic Area) | (ppba) | Resistivity (ppba) | Curve (ppba) | Sample |
| Indium | −2.112 | −3.42 | 0.0004 | 0.0003 | −9.30% |
| Indium | −1.423 | −2.803 | 0.0016 | 0.0018 | 14.30% |
| Indium | −0.338 | −1.642 | 0.0228 | 0.0241 | 5.70% |
| Indium | −0.032 | −1.26 | 0.055 | 0.0501 | −8.80% |
| Indium | 0.757 | −0.241 | 0.574 | 0.3317 | −42.20% |
| Indium | −1.862 | −3.089 | 0.0008 | 0.0006 | −23.00% |
| Indium | −0.6 | −1.854 | 0.014 | 0.0129 | −8.10% |
| Indium | −1.428 | −2.838 | 0.0015 | 0.0018 | 22.30% |

TABLE 5
Gallium Resistivity and PL Data

| | | | | Probe-tip | Slice | Thick- | Probe Head |
|---|---|---|---|---|---|---|---|
| | | Recipe | Sample | Spacing | Diameter | ness | Correction |
| Dopant | Type | Type¹ | No. | (mm) | (mm) | (mm) | Factor |
| Gallium | Primary | 100 | 349888 | 1 | 14.95 | 2.121 | 0.992 |
| | | | | 1 | 14.95 | 2.121 | 0.992 |
| | | | | 1 | 14.95 | 2.121 | 0.992 |
| | | | | 1 | 14.95 | 2.121 | 0.992 |
| Gallium | Primary | 100 | 349160 | 1 | 17.55 | 2.129 | 0.992 |
| | | | | 1 | 17.55 | 2.129 | 0.992 |
| | | | | 1 | 17.55 | 2.129 | 0.992 |
| | | | | 1 | 17.55 | 2.129 | 0.992 |
| Gallium | Primary | 1000 | 350081 | 1 | 14.9 | 2.112 | 0.992 |
| | | | | 1 | 14.9 | 2.112 | 0.992 |
| | | | | 1 | 14.9 | 2.112 | 0.992 |
| | | | | 1 | 14.9 | 2.112 | 0.992 |
| Gallium | Primary | 10000 | 350074 | 1 | 14.05 | 2.104 | 0.992 |
| | | | | 1 | 14.05 | 2.104 | 0.992 |
| | | | | 1 | 14.05 | 2.104 | 0.992 |
| | | | | 1 | 14.05 | 2.104 | 0.992 |
| Gallium | Back-Up | 10000 | 349891 | 1 | 16.46 | 2.108 | 0.992 |
| | | | | 1 | 16.46 | 2.108 | 0.992 |
| | | | | 1 | 16.46 | 2.108 | 0.992 |
| | | | | 1 | 16.46 | 2.108 | 0.992 |
| Gallium | Back-Up | 100 | 350078 | 1 | 15.9 | 2.103 | 0.992 |
| | | | | 1 | 15.9 | 2.103 | 0.992 |
| | | | | 1 | 15.9 | 2.103 | 0.992 |
| | | | | 1 | 15.9 | 2.103 | 0.992 |

| | | | | | | | | | Sheet |
|---|---|---|---|---|---|---|---|---|---|
| Dopant | S/D | F2 | w/S | F(w/s) | F | Voltage | Current (I) | Resistance | Resistance |
| Gallium | 0.067 | 4.373 | 4.373 | 0.3 | 2.757 | 1.22E−04 | 1.50E−09 | 81584.633 | 224956.99 |
| | 0.067 | 4.373 | 4.373 | 0.3 | 2.757 | 1.27E−04 | 1.50E−09 | 84845.467 | 233948.23 |
| | 0.067 | 4.373 | 4.373 | 0.3 | 2.757 | 1.20E−04 | 1.50E−09 | 80172.767 | 221063.99 |
| | 0.067 | 4.373 | 4.373 | 0.3 | 2.757 | 1.27E−04 | 1.50E−09 | 84744.5 | 233669.83 |
| Gallium | 0.057 | 4.432 | 4.432 | 0.293 | 2.743 | 1.00E−04 | 1.20E−08 | 8345.0258 | 22892.615 |
| | 0.057 | 4.432 | 4.432 | 0.293 | 2.743 | 9.76E−05 | 1.20E−08 | 8134.935 | 22316.28 |
| | 0.057 | 4.432 | 4.432 | 0.293 | 2.743 | 9.58E−05 | 1.20E−08 | 7983.6483 | 21901.261 |
| | 0.057 | 4.432 | 4.432 | 0.293 | 2.743 | 1.03E−04 | 1.20E−08 | 8567.7238 | 23503.535 |
| Gallium | 0.067 | 4.371 | 4.371 | 0.307 | 2.813 | 9.54E−04 | 2.75E−07 | 3470.3751 | 9762.2087 |
| | 0.067 | 4.371 | 4.371 | 0.307 | 2.813 | 9.47E−04 | 2.75E−07 | 3441.9544 | 9682.2608 |
| | 0.067 | 4.371 | 4.371 | 0.307 | 2.813 | 9.39E−04 | 2.75E−07 | 3413.7185 | 9602.8331 |
| | 0.067 | 4.371 | 4.371 | 0.307 | 2.813 | 9.63E−04 | 2.75E−07 | 3501.7284 | 9850.4058 |
| Gallium | 0.071 | 4.347 | 4.347 | 0.314 | 2.846 | 1.61E−04 | 8.00E−08 | 2011.8794 | 5726.6758 |
| | 0.071 | 4.347 | 4.347 | 0.314 | 2.846 | 1.49E−04 | 8.00E−08 | 1859.9838 | 5294.3152 |
| | 0.071 | 4.347 | 4.347 | 0.314 | 2.846 | 1.48E−04 | 8.00E−08 | 1848.6379 | 5262.0202 |
| | 0.071 | 4.347 | 4.347 | 0.314 | 2.846 | 1.61E−04 | 8.00E−08 | 2016.2962 | 5739.2478 |
| Gallium | 0.061 | 4.41 | 4.41 | 0.31 | 2.863 | 1.13E−04 | 9.00E−08 | 1255.5373 | 3594.2554 |
| | 0.061 | 4.41 | 4.41 | 0.31 | 2.863 | 1.10E−04 | 9.00E−08 | 1224.1592 | 3504.4287 |
| | 0.061 | 4.41 | 4.41 | 0.31 | 2.863 | 1.12E−04 | 9.00E−08 | 1246.5712 | 3568.5879 |
| | 0.061 | 4.41 | 4.41 | 0.31 | 2.863 | 1.16E−04 | 9.00E−08 | 1290.2722 | 3693.6919 |
| Gallium | 0.063 | 4.397 | 4.397 | 0.315 | 2.885 | 2.63E−04 | 1.00E−07 | 2628.0505 | 7582.6795 |
| | 0.063 | 4.397 | 4.397 | 0.315 | 2.885 | 2.62E−04 | 1.00E−07 | 2622.504 | 7566.6763 |
| | 0.063 | 4.397 | 4.397 | 0.315 | 2.885 | 2.65E−04 | 1.00E−07 | 2645.697 | 7633.5947 |
| | 0.063 | 4.397 | 4.397 | 0.315 | 2.885 | 2.68E−04 | 1.00E−07 | 2676.46 | 7722.3548 |

| | Average | | Temp. | Temp. | | | Phosphorus |
|---|---|---|---|---|---|---|---|
| | Sheet | Average | Correction | Correction | Temp. | Final | by PL |
| Dopant | Resistance | Resistivity | (C_{T}) | Factor (FT) | (° C.) | Resistivity | (ppba) |
| Gallium | 228409.759 | 48445.71 | 0.01 | 0.963 | 26.828 | 46654.803 | 0.0343 |
| Gallium | 22653.423 | 4822.914 | 0.009 | 0.965 | 26.822 | 4653.3882 | 0.0273 |
| Gallium | 9724.427 | 2053.799 | 0.009 | 0.966 | 26.772 | 1983.8751 | 0.0282 |
| Gallium | 5505.565 | 1158.371 | 0.009 | 0.966 | 26.811 | 1119.0318 | 0.0294 |
| Gallium | 3590.241 | 756.823 | 0.009 | 0.966 | 26.811 | 731.36615 | 0.0467 |
| Gallium | 7626.326 | 1603.816 | 0.009 | 0.966 | 26.772 | 1549.5119 | 0.056 |

| | Boron | Aluminum | Donor | Donor | Net Donor | Instrinsic | Gallium |
|---|---|---|---|---|---|---|---|
| | by PL | by PL | by PL | by Resist | Amt. = Gallium | Silicon | Peak |
| Dopant | (ppba) | (ppba) | (ppba) | (ppba) | (ppba) | Peak Area² | Area³ |
| Gallium | 0.0347 | 0 | 0.0004 | 0.0057 | 0.005 | 22.859 | 1.065 |
| Gallium | 0.0691 | 0 | 0.0418 | 0.0569 | 0.015 | 22.072 | 2.277 |
| Gallium | 0.0806 | 0 | 0.0524 | 0.1336 | 0.081 | 26.455 | 8.619 |
| Gallium | 0.0665 | 0 | 0.0371 | 0.2368 | 0.2 | 20.889 | 13.99 |
| Gallium | 0.1049 | 0 | 0.0582 | 0.3623 | 0.304 | 15.851 | 14.759 |
| Gallium | 0.2107 | 0 | 0.1547 | 0.171 | 0.016 | 12.369 | 1.285 |

| | log(Gallium | log(Net | Assigned Calibra- | Gallium Calculation | Fit between |
|---|---|---|---|---|---|
| | Area/Intrin- | Donor Amt.) | tion Value per | per Calibration | Curve and |
| Dopant | sic Area) | (ppba) | Resistivity (ppba) | Curve (ppba) | Sample |
| Gallium | −1.332 | −2.277 | 0.0053 | 0.0052 | −0.80% |
| Gallium | −0.986 | −1.82 | 0.0151 | 0.0157 | 3.50% |
| Gallium | −0.487 | −1.091 | 0.0812 | 0.0765 | −5.80% |
| Gallium | −0.174 | −0.7 | 0.1997 | 0.2065 | 3.40% |
| Gallium | −0.031 | −0.517 | 0.3041 | 0.3251 | 6.90% |
| Gallium | −0.984 | −1.787 | 0.0163 | 0.0158 | −3.10% |

### Summary of Examples:

Quantities of Ga or In provided from traceable NIST Standards are used to treat particulate silicon. After drying, the treated particulate silicon is measured into hollowed out silicon tubes (vessels). The vessels are packed with the treated silicon, and the vessels are swept into single crystal using float-zone pullers. Sample slices that can be measured on PL instrumentation are prepared from these vessel cores and qualitative measurements of In or Ga are observed using PL technology.

To quantify the PL spectra, 3 alternate test methodologies (4-point resistivity, low temperature FTIR, and total dissolution of samples followed by ICP-MS evaluation) are evaluated. Ultimately, 4-point resistivity is chosen as the means to assign quantitative values for the PL slices. This permitted final calibration of the PL instruments. As such, the instant disclosure is useful for reporting of quantified In and Ga values for silane epitaxial samples run on the PL instruments.

Segregation values appropriate for the zoning conditions are identified for the In and Ga species. In total, a set of primary and back-up PL calibration standards are created for both the In and the Ga impurities. Table B provides such standards below:

TABLE B
Calibration Standards

| Sample No. | Component | Status | Value (ppba) |
|---|---|---|---|
| 352607 | Indium | primary | 0.0004 |
| 352608 | Indium | primary | 0.0016 |
| 351974 | Indium | primary | 0.0228 |
| 352669 | Indium | primary | 0.055 |
| 351969 | Indium | back-up | 0.0008 |
| 352834 | Indium | back-up | 0.0015 |
| 352494 | Indium | back-up | 0.014 |
| 352670 | Indium | back-up | 0.574 |
| 349888 | Gallium | primary | 0.0053 |
| 349160 | Gallium | primary | 0.0151 |
| 350081 | Gallium | primary | 0.0812 |
| 350074 | Gallium | primary | 0.1997 |
| 350078 | Gallium | back-up | 0.0163 |
| 349891 | Gallium | back-up | 0.3041 |

It is to be understood that the appended claims are not limited to express and particular compounds, compositions, or methods described in the detailed description, which may vary between particular embodiments which fall within the scope of the appended claims. With respect to any Markush groups relied upon herein for describing particular features or aspects of various embodiments, it is to be appreciated that different, special, and/or unexpected results may be obtained from each member of the respective Markush group independent from all other Markush members. Each member of a Markush group may be relied upon individually and or in combination and provides adequate support for specific embodiments within the scope of the appended claims.

It is also to be understood that any ranges and subranges relied upon in describing various embodiments of the present invention independently and collectively fall within the scope of the appended claims, and are understood to describe and contemplate all ranges including whole and/or fractional values therein, even if such values are not expressly written herein. One of skill in the art readily recognizes that the enumerated ranges and subranges sufficiently describe and enable various embodiments of the present invention, and such ranges and subranges may be further delineated into relevant halves, thirds, quarters, fifths, and so on. As just one example, a range “of from 0.1 to 0.9” may be further delineated into a lower third, i.e., from 0.1 to 0.3, a middle third, i.e., from 0.4 to 0.6, and an upper third, i.e., from 0.7 to 0.9, which individually and collectively are within the scope of the appended claims, and may be relied upon individually and/or collectively and provide adequate support for specific embodiments within the scope of the appended claims. In addition, with respect to the language which defines or modifies a range, such as “at least,” “greater than,” “less than,” “no more than,” and the like, it is to be understood that such language includes subranges and/or an upper or lower limit. As another example, a range of “at least 10” inherently includes a subrange of from at least 10 to 35, a subrange of from at least 10 to 25, a subrange of from 25 to 35, and so on, and each subrange may be relied upon individually and/or collectively and provides adequate support for specific embodiments within the scope of the appended claims. Finally, an individual number within a disclosed range may be relied upon and provides adequate support for specific embodiments within the scope of the appended claims. For example, a range “of from 1 to 9” includes various individual integers, such as 3, as well as individual numbers including a decimal point (or fraction), such as 4.1, which may be relied upon and provide adequate support for specific embodiments within the scope of the appended claims.

The present invention has been described herein in an illustrative manner, and it is to be understood that the terminology which has been used is intended to be in the nature of words of description rather than of limitation. Many modifications and variations of the present invention are possible in light of the above teachings. The present invention may be practiced otherwise than as specifically described within the scope of the appended claims. The subject matter of all combinations of independent and dependent claims, both single and multiple dependent, is herein expressly contemplated.

1. A method of forming doped monocrystalline silicon, comprising:
providing a vessel comprising silicon and defining a cavity;
providing particulate silicon;
providing a dopant;
providing a float-zone apparatus;
combining the particulate silicon and the dopant to form treated particulate silicon;
disposing the treated particulate silicon into the cavity of the vessel; and
float-zone processing the vessel and the treated particulate silicon into the doped monocrystalline silicon with the float-zone apparatus.

2. The method as set forth in claim 1, wherein providing a dopant is further defined as providing a solution comprising a dopant and a solvent.

3. The method as set forth in claim 2, wherein combining the particulate silicon and the dopant is further defined as mixing the solution and the particulate silicon to obtain wet particulate silicon, and drying the wet particulate silicon to form treated particulate silicon.

4. The method as set forth in claim 2, wherein disposing the treated particulate silicon into the cavity of the vessel is further defined as orienting and packing the treated particulate silicon into the cavity of the vessel.

5. The method as set forth in claim 1, further comprising of cleaning at least one of the vessel and the particulate silicon prior to disposing the treated particulate silicon into the cavity of the vessel.

6. The method as set forth in claim 1, wherein the particulate silicon comprises polycrystalline silicon.

7. The method as set forth in claim 1, wherein:
i) the particulate silicon is free of the dopant prior to combining the particulate silicon and the dopant,
ii) the vessel is free of the dopant prior to disposing the treated particulate silicon into the cavity of the vessel, or
iii) both i) and ii).

8. The method as set forth in claim 1, further comprising:
providing a cap comprising silicon with the cap complimentary sized and shaped for closing the cavity of the vessel, and
disposing the cap to close the cavity after disposing the treated particulate silicon into the cavity of the vessel.

9. The method as set forth in claim 1, wherein the dopant comprises;
i) indium (In),
ii) gallium (Ga), or
iii) a combination of i) and ii).

10. The method as set forth in claim 1, wherein the dopant comprises;
i) antimony (Sb), aluminum (Al), arsenic (As), bismuth (Bi), thallium (Tl), or combinations thereof,
ii) boron (B), phosphorous (P), or a combination thereof, or
iii) a transition metal.

11. The method as set forth in claim 1, wherein the dopant is present in the doped monocrystalline silicon in an amount of from about 0.0001 to about 2000 parts per trillion atoms.

12. Doped monocrystalline silicon formed according to the method as set forth in claim 1.

13. A method of analyzing the concentration of a dopant in doped monocrystalline silicon, comprising:
providing a vessel comprising silicon and defining a cavity;
providing particulate silicon;
providing a dopant;
providing a float-zone apparatus;
providing an instrument for measuring levels of the dopant;
combining the particulate silicon and the dopant to form treated particulate silicon;
disposing the treated particulate silicon into the cavity of the vessel;
float-zone processing the vessel and the treated particulate silicon into the doped monocrystalline silicon with the float-zone apparatus;
removing a piece of the doped monocrystalline silicon; and
determining the concentration of the dopant in the piece of doped monocrystalline silicon with the instrument.

14. The method as set forth in claim 13, wherein the instrument is a photoluminescence (PL) instrument.

15. The method as set forth in claim 13, further comprising calibrating the instrument prior to determining the concentration of the dopant in the piece of doped monocrystalline silicon.

16. The method as set forth in claim 15, wherein calibrating the instrument is further defined as providing calibration standards and entering the calibration standards into the instrument to quantify the concentration of the dopant in the piece of doped monocrystalline silicon.

17. The method as set forth in claim 16, wherein the calibration standards are provided by testing the surface resistivity of a doped monocrystalline silicon wafer having a predetermined level of doping.

18. The method as set forth in claim 13, wherein the particulate silicon comprises polycrystalline silicon.

19. The method as set forth in claim 13, wherein the dopant comprises;
i) indium (In),
ii) gallium (Ga), or
iii) a combination of i) and ii).

20. The method as set forth in claim 13, wherein the dopant is present in the piece of doped monocrystalline silicon in an amount of from about 0.0001 to about 2000 parts per trillion atoms.
